(19) United States
(12) Patent Application Publication
(10) Pub. No.: US 2004/0130399 A1
(43) Pub. Date: Jul. 8, 2004

(54) Low noise amplifiers

(76) Inventors: Pietro Andreani, Lund (SE); Henrik Sjoland, Loddekopinge (SE)

Correspondence Address: BURNS DOANE SWECKER & MATHIS L L P, POST OFFICE BOX 1404, ALEXANDRIA, VA, 22313-1404, US

(21) Appl. No.: 10/474,337

(22) PCT Filed: Apr. 8, 2002
(86) PCT No.: PCT/EP02/03889

(30) Foreign Application Priority Data
Apr. 9, 2001 (GB) 0108890.5

(51) Int. Cl. H03F 1/22

(52) U.S. Cl. 330/311

(57) ABSTRACT

A low noise amplifier comprises a CMOS transistor (M₁) having gate, source and drain terminals, the gate terminal being connected via a first impedance matching network (L_{g}) to an input terminal of the amplifier, and the source terminal being connected via a second impedance matching network (Lₛ) to a signal ground connection, and a capacitive impedance (C_{d}) connected between the gate terminal and the source terminal of the transistor (M₁).

### BACKGROUND OF THE INVENTION

When a weak radio signal is received, it must first be amplified before further processing. The amplifier performing this function must add as little noise as possible to the signal. Such an amplifier is referred to as a Low-Noise Amplifier (LNA). Apart from low noise, the amplifier must also have a well determined resistive input impedance to enable the filter that typically precedes the amplifier to operate as desired. To understand the importance of LNAs, it should be noted that the noise-figure of a radio receiver can never be less than that of the LNA in the receiver.

In a high performance radio receiver the first block is always a low noise amplifier (LNA), noise performance of which sets a limit to that of the entire receiver. Therefore, if CMOS technology is to be used in demanding applications, it is important to be able to design CMOS LNAs with very low noise. In general, the requirements on an LNA are, apart from low noise, also high linearity, sufficiently high gain, well-defined resistive input impedance (to match the passive off-chip filter that precedes the LNA in almost all radio receivers), and low power consumption.

There are several alternatives how to obtain a resistive input impedance. For instance, one can use a common-gate topology, so that the input conductance becomes equal to the transconductance of the transistor. The best noise performance, however, is achieved with inductive source degeneration, an example of which is illustrated in FIG. 1 of the accompanying drawings.

The circuit of FIG. 1 comprises two transistors M₁ and M₂ . Each transistor has gate, drain and source connections G, D and S respectively, the first transistor having its source connected to ground via an impedance LS and its gate G connected to an input of the circuit via an inductance LG. In the circuit of FIG. 1 RS represents the source output impedance and VS represents the input voltage. The second transistor M₂ has its source connection connected to the drain connection of the first transistor M₁ and its drain connection connected a supply voltage VCC via an output inductance Lₒᵤₜ . The gate connection of the second transistor M₂ is connected to the supply voltage VCC. The drain connection of the second transistor provides an output Vₒᵤₜ of the circuit.

An inductor Lₛ is inserted in series with the source (emitter) of the input transistor m₁. Together with the intrinsic gate-source (base-emitter) capacitance, this results in a resistive part of the input impedance. The inductor Lₛ will have a small inductance, and will introduce little noise even if it is a low quality on-chip component. The input. impedance will be capacitive and resistive, which can be transformed to the desired impedance by an inductive matching network. A problem of this topology is the sensitivity to gate induced current noise, since such noise is enhanced by the Q-factor in the input circuit. A high Q is beneficial for reducing channel current noise, however, and in a design where the gate induced current noise is disregarded one might end up with a large Q, and a noise totally dominated by the gate induced current noise.

For example, in CMOS, gate-induced noise is a problem that limits the achievable performance.

### SUMMARY OF THE PRESENT INVENTION

According to one aspect of the present invention, there is provided an input device which decreases the amount of noise current injected at the input. To achieve the same input impedance, an additional capacitor is introduced between gate and source (base and emitter) of the input device. If this capacitance is of high quality, it introduces very low noise, and the total noise of the amplifier can be significantly reduced.

### BRIEF DESCRIPTION OF THE DRAWINGS

FIG. 1 illustrates a low noise amplifier with inductive source degeneration;

FIG. 2 illustrates a low noise amplifier embodying the present invention;

FIG. 3 illustrates a MOS transistor;

FIG. 4 illustrates a small signal circuit for noise calculations; and

FIG. 5 illustrates a plot of noise figure against transistor Q and width.

### DETAILED DESCRIPTION OF THE PREFERRED EMBODIMENT

Although the present invention is described with reference to a MOS transistor, it will be readily appreciated that the principles can be applied to any transistor which exhibits a gate (or equivalent) noise related to the gate (or equivalent) capacitance.

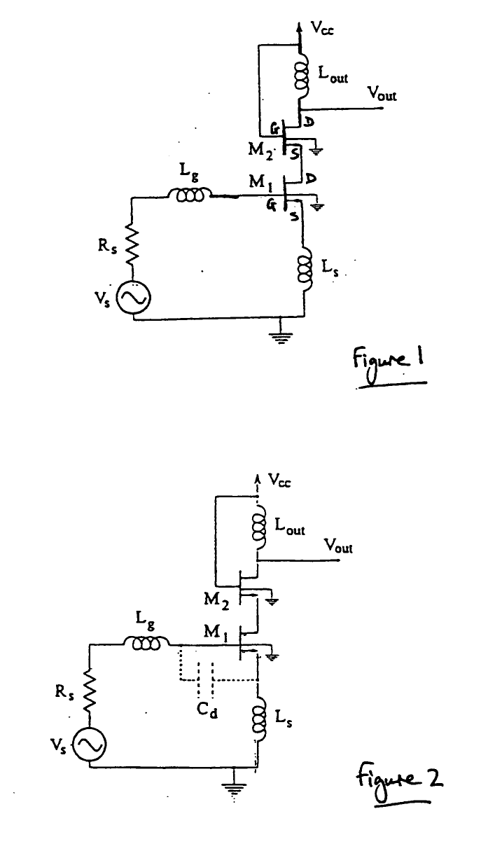

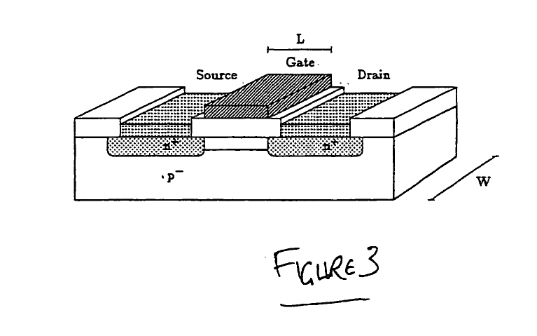

FIG. 2 illustrates an embodiment of the present invention, which includes first and second transistors M₁ and M₂ connected with one another and other components as shown in the FIG. 1 circuit.

In the embodiment of the present invention illustrated in FIG. 2, an additional capacitance C_{d} is provided in parallel to the intrinsic gate capacitance C_{gs} of transistor M₁. The additional capacitance C_{d} has the effect of decoupling Q from C_{gs}, which allows for an adjustable reduction of Q for any given value of C_{gs}. This can be very important, since the gate induced current noise grows with the square of C_{gs}.

In the following description, it will be shown that such a technique allows for the design of very low noise CMOS LNAs, without any associated power consumption penalties. In order to render the analysis manageable, all passive components will be treated as lossless. Thus, the calculated noise figures will represent minimum values for the available technology, design specifications, and power consumption levels.

FIG. 2 shows a simplified schematic of an LNA embodying the invention. Transistor M₂ has a minor influence on the noise behaviour of the LNA, and its contribution to the total noise is disregarded in the analysis. Table 1 summarizes a number of symbols used in the following, where the transistor referred to is M₁. The treatment will be confined to the case of a long-channel (or better, low-electric-field) transistor, for which the usual quadratic I_{ds}-V_{gs} relation applies in the saturation region. For example, see “Operation and modelling of the MOS Transistor”, Yannis P. Tsiridis, 2nd Edition, McGraw-Hill 1999 for a detailed explanation of a MOS transistor. FIG. 3 illustrates a MOS transistor structure, and in particular illustrates the transistor width W and gate length L.

TABLE 1
Process and design parameters

| Symbol | Parameter |
|---|---|
| W | Transistor width |
| L | Transistor length |
| I_{ds} | Transistor channel current |
| V_{ds} | Transistor drain-source voltage |
| V_{gs} | Transistor gate-source voltage |
| C_{gs} | Transistor gate-source capacitance |
| gₘ | Transistor transconductance |
| G_{mb} | Transistor bulk transconductance |
| G_{do} | Transistor output conductance for V_{ds} = 0 |
| μₙ | Electron mobility |
| Cₒₓ | Gate unit capacitance |
| γ | Channel current noise factor |
| δ | Gate induced current noise factor |
| Rₛ | Source resistance |
| ωₒ | Angular frequency of operation |
| k_{B} | Boltzmann's constant |
| T | Absolute temperature |

It is well-known that the input impedance of the circuit (neglecting g_{mb}, whose influence on both input impedance and output noise is minimal) is given by

$${Z}_{i n} = {R}_{s} + \frac{1}{j ω {C}_{t}} + j ω {L}_{t} + {g}_{m} \frac{{L}_{s}}{{C}_{t}} \qquad ( 1 )$$

where Lₜ=L_{g}+Lₛ and Cₜ=C_{d}+C_{gs}: gₘ can be written, in the usual long-channel approximation, as

gₘ=\sqrt{2 μₙCₐₓWI_{ds}|L} (2)

At the resonance (operating) angular frequency

$$ω = \frac{1}{\sqrt{{L}_{t} {C}_{t}}} \qquad ( 3 )$$

the impedance presented by the LNA must be equal to the source impedance matching; thus, the resulting total impedance at resonance is

$${Z}_{i n , r e s} = {R}_{s} + {g}_{m} \frac{{L}_{s}}{{C}_{t}} = 2 {R}_{s} \qquad ( 4 )$$

where the equality

$${g}_{m} \frac{{L}_{s}}{{C}_{t}} = {R}_{s} \qquad ( 5 )$$

must be fulfilled. The quality factor Q of the input circuit is then

$$Q = \frac{1}{2 {R}_{s} {ω}_{o} {C}_{t}} \qquad ( 6 )$$

The small signal equivalent circuit for the noise analysis is shown in FIG. 3. Three noise sources have been included: the thermal noise of the source resistance (i_{n,R}), the thermal noise of the channel current (i_{n,d}), and the gate induced current noise (i_{n,g}) The corresponding noise densities are:

$${\overline{{i}^{2}}}_{n , R} = 4 {k}_{B} T \frac{1}{{R}_{s}} Δ f \qquad ( 7 )$$

i^{\overline{2}}_{n,d}=4k_{B}T γg_{do}Δƒ (8)

$${\overline{{i}^{2}}}_{n , g} = 4 {k}_{B} T \frac{{δ ( ω {C}_{g s} )}^{2}}{5 {g}_{d o}} Δ f \qquad ( 9 )$$

The correlation between gate induced current noise and channel current noise has been disregarded. Such noise can be readily shown to introduce only a very small error.

Conventional circuit analysis gives the transfer function of the three noise sources to the output noise current i_{n,out} (see FIG. 3) at resonance:

$$\begin{matrix}{i}_{n , out , R} = \frac{{g}_{m}}{j 2 {ω}_{o} {C}_{t}} {i}_{n , R} & ( 10 ) \\ {i}_{n , out , d} = \frac{1}{2} {i}_{n , d} & ( 11 ) \\ {i}_{n , out , g} = \frac{{g}_{m}}{{jω}_{o} {C}_{t}} \frac{j {R}_{s} {ω}_{o} {C}_{t} - 1}{j 2 {R}_{s} {ω}_{o} {C}_{t}} {i}_{n , g} & ( 12 )\end{matrix}$$

Making use of equation (6), the following noise figure is obtained at resonance:

$$\begin{matrix}\begin{matrix}F = \frac{{\overline{{i}^{2}}}_{n , out , R} + {\overline{{i}^{2}}}_{n , out , g} + {\overline{{i}^{2}}}_{n , out , d}}{{\overline{{i}^{2}}}_{n , out , R}} \\ = 1 + \frac{\frac{δ {g}_{m}^{2}}{5 {g}_{d o}} ( {Q}^{2} + \frac{1}{4} ) {P}^{2} + \frac{γ}{4} {g}_{d o}}{{R}_{s} {Q}^{2} {g}_{m}^{2}} \\ = 1 + \frac{\frac{δ}{5} ( {Q}^{2} + \frac{1}{4} ) {P}^{2} + \frac{γ}{4}}{{R}_{s} {Q}^{2} {g}_{m}}\end{matrix} & ( 13 ) \\ where \\ P ≡ \frac{{C}_{g s}}{{C}_{t}} & ( 14 )\end{matrix}$$

and the long-channel regime simplification g_{do}=gₘ has been made. The commonly used expression

$${C}_{gs} = \frac{2}{3} {C}_{o x} W L \qquad ( 15 )$$

will be adopted in the following. Using equations (6), (14), and (15), P can be expressed as

$$P = Q \cdot 2 {ω}_{0} {R}_{s} {C}_{g s} = Q \cdot \frac{4}{3} {ω}_{o} {R}_{s} {C}_{o x} W L \qquad ( 16 )$$

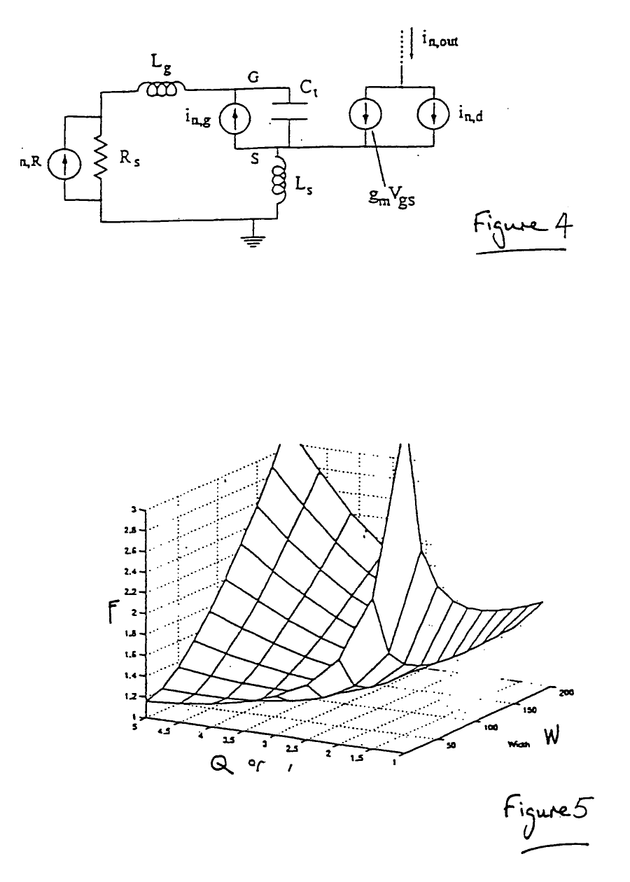

Equation (13) can be rewritten (using equations (2) and (16)) as

$$\begin{matrix}F = 1 + \frac{\frac{δ}{5} ( {Q}^{2} + \frac{1}{4} ) {( Q \cdot \frac{4}{3} {ω}_{o} {R}_{s} {C}_{o x} W L )}^{2} + \frac{γ}{4}}{{R}_{s} {Q}_{2} \sqrt{2 {μ}_{n} {C}_{o x} W {I}_{d s} / L}} \\ ≡ 1 + a {Q}^{2} {W}^{\frac{3}{2}} + \frac{a}{4} {W}^{\frac{3}{2}} + b {Q}^{- 2} {W}^{- \frac{1}{1}}\end{matrix} \qquad ( 17 )$$

where the expressions for a and b are obvious. A typical plot of expression (17) as a function of Q and W is shown in FIG. 4. It is straightforward to check that expression (17) does not have a minimum for finite values of Q and W; rather, it can be made arbitrarily close to unity for any value of I_{ds}. However, this condition is approached when Q tends to infinity and W tends to zero, which are not reasonable choices for these parameters. In practice, Q must be limited for reasons such as linearity and sensitivity to parameter variations, and W must be large enough to allow for a given I_{ds}. A Q value can therefore be fixed which will be the maximum possible that can be tolerated, and derive and expression for the optimal transistor width Wₒₚₜ in presence of such a Q. Taking the derivative of expression (17) with respect to W yields

$$\frac{\partial F}{\partial W} = \frac{3}{2} a ( {Q}^{2} + \frac{1}{4} ) {W}^{\frac{1}{2}} - \frac{1}{2} b {Q}^{- 2} {W}^{- \frac{3}{2}} \qquad ( 18 )$$

Equating expression (18) to zero gives Wₒₚₜ as

$$\begin{matrix}{W}_{opt} = \frac{1}{{Q ( {Q}^{2} + \frac{1}{4} )}^{\frac{1}{2}}} \sqrt{\frac{b}{3 a}} \approx \frac{1}{{Q}^{2}} \sqrt{\frac{b}{3 a}} \\ = \frac{1}{{Q}^{2}} \sqrt{\frac{5 γ}{12 δ}} \frac{1}{\frac{4}{3} {ω}_{o} {R}_{s} {C}_{o x} L}\end{matrix} \qquad ( 19 )$$

The corresponding value for Pₒₚₜ is obtained by inserting expression (19) in expression (16):

$${P}_{opt} = \frac{1}{{( {Q}^{2} + \frac{1}{4} )}^{\frac{1}{2}}} \sqrt{\frac{5 γ}{12 δ}} \approx \frac{1}{Q} \sqrt{\frac{5 γ}{12 δ}} \qquad ( 20 )$$

Finally, the minimum value of the noise factor Fₘᵢₙ, for a given Q, can be obtained from expressions (17) and (19):

$$\begin{matrix}{F}_{min} = 1 + \frac{{( {Q}^{2} + \frac{1}{4} )}^{\frac{1}{4}}}{{Q}^{\frac{3}{2}}} \cdot 4 {{a}^{\frac{1}{4}} ( \frac{b}{3} )}^{\frac{3}{4}} \approx 1 + \frac{1}{Q} \cdot 4 {{a}^{\frac{1}{4}} ( \frac{b}{3} )}^{\frac{3}{4}} \\ = 1 + \frac{1}{Q} \cdot 4 {( \frac{δ}{5} )}^{\frac{1}{4}} {( \frac{γ}{12} )}^{\frac{3}{4}} \sqrt{\frac{2 {ω}_{0}}{3 {μ}_{n} {R}_{s} {I}_{d s}}} L\end{matrix} \qquad ( 21 )$$

It is possible to compare the above noise figure to what can be achieved without the extra capacitor C_{d}, for the same value of Q and I_{ds}. We therefore define the suppression factor S as

$$S ≡ \frac{{F}_{P = 1} - 1}{{F}_{min} - 1} \qquad ( 22 )$$

where F_{P=1} is given by expression (13) with P=1. Accordingly:

$$S = \frac{\frac{δ}{5} ( {Q}^{2} + \frac{1}{4} ) + \frac{γ}{4}}{\frac{δ}{5} ( {Q}^{2} + \frac{1}{4} ) {P}_{opt}^{2} + \frac{γ}{4}} \sqrt{\frac{{W}_{opt}}{{W}_{p = 1}}} \qquad ( 23 )$$

with W_{P=1} from expressions (6) and (15):

$${W}_{P = 1} = \frac{1}{Q \cdot \frac{4}{3} {ω}_{o} {R}_{s} {C}_{o x} L} \qquad ( 24 )$$

Expressions (19), (20), and (24) yield

$$S = ( \frac{3 δ}{5 γ} {Q}^{2} + \frac{3}{4} ) \sqrt{\frac{1}{Q} \sqrt{\frac{5 δ}{12 δ}}} \qquad ( 25 )$$

Fₘᵢₙ can be written as

$${F}_{min} = 1 + \frac{{F}_{P = 1} - 1}{S} \qquad ( 26 )$$

Thus, the higher S, the larger the improvement on Fₘᵢₙ. In the limit of a high Q, S is proportional to Q^{3/2}.

The relations found above lead to a realizable amplifier, that is, all design parameters can be assigned reasonable values. In the description below, process parameters are taken from a standard 0.35μm CMOS process, where δ=2γ (a recent simulation-based analysis of the values for γ and δ is found in Proceedings CICC 1999, paper 16-2, May 1999, where the symbol β is used instead of δ). The operating (resonance) frequency is 1.8 GHz, the source impedance is 50Ω, and the current consumption is set to 1 mA. Table 2 summarizes both process and design data.

The design procedure is started by fixing Q at the moderately high value of three. Expressions (19) and (20) then give Wₒₚₜ=35 μm and P=0.15, respectively. From expression (15) we obtain C_{gs}=44fF, and from expression (14) C_{d}=250fF. Expressions (2) and (5) yield respectively gₘ=5.8 mA/V and Lₛ=2.5 nH. Finally, L_{g} calculated from expression (3) is 24 nH. Clearly, all components (except possibly 1_{g}) have integratable values.

Expression (21) gives Fₘᵢₙ=1.26 (=0.99 dB), which is a very low value. From the suppression factor S=4.59 we can calculate the value of F when P=1, resulting in Fₚ₌₁=2.18 (=3.38 dB), a much higher value. Table 3 shows the component values for the cases Q=2 and Q=4 as well.

TABLE 2
Process and design parameter values.

| Parameter | Value |
|---|---|
| Lₘᵢₙ (eff). | 0.4 μm |
| μₙ | 0.04 m²/V |
| Cₒₓ | 4.710⁻³ F/m² |
| γ | 2.0 |
| δ | 4.0 |
| I_{ds} | 1 mA |
| ωₒ | 2π. 1.8 10⁹ₛ−1 |
| Rₛ | 50 Ω |

TABLE 3
Component values and noise performance of the
amplifier.

| | Q = 2 | Q = 3 | Q = 4 |
|---|---|---|---|
| W | 78 μm | 35 μm | 20 μm |
| P | 0.22 | 0.15 | 0.11 |
| C_{gs} | 98 fF | 44 fF | 25 fF |
| C_{d} | 344 fF | 250 fF | 196 fF |
| Lₛ | 2.58 nH | 2.56 nH | 2.55 nH |
| L_{g} | 15.1 nH | 24.0 nH | 32.8 nH |
| Fₘᵢₙ | 1.38 dB | 0.99 dB | 0.76 dB |
| F_{p = 1} | 3.16 dB | 3.38 dB | 3.64 dB |
| S | 2.75 | 4.59 | 6.81 |

It will be readily apparent that the embodiments of the invention presented above allow for the design of very low noise CMOS LNAs at low power consumption levels.

The principles of the invention of applicable to differential low noise amplifiers as well as to the INA illustrated and described above. In the case of a differential LNA, the source terminal would be connected to the signal ground (or common) terminal via an impedance matching network such as an inductor.

The principles of the invention are also applicable to transistors in general, for example bipolar transistors. In the case of bipolar transistors, the input and “supply” terminals are provided by the base, emitter and collector.

1. A low noise amplifier comprising:
a CMOS transistor having gate, source and drain terminals, the gate terminal being connected via a first impedance matching network to an input terminal of the amplifier, and the source terminal being connected via a second impedance matching network to a signal ground connection; and
a capacitive impedance connected between the gate terminal and the source terminal of the transistor.

2. A low noise amplifier comprising a transistor having an input terminal and first and second supply terminals, and a capacitive impedance connected between the input terminal and one of the first and second supply terminals.

3. A low noise amplifier comprising:
a bipolar transistor having base, emitter and collector terminals, the base terminal being connected via a first impedance matching network to an input terminal of the amplifier and the emitter terminal being connected via a second impedance matching network to a signal ground terminal;
a capacitive impedance connected between the base and emitter terminals of the transistor.
